(19) United States
(12) Patent Application Publication
(10) Pub. No.: US 2026/0324175 A1
(43) Pub. Date: Oct. 15, 2026

(54) DISPLAY DEVICE

(71) Applicant: LG Display Co., Ltd., Seoul (KR)

(72) Inventors: Sumin LEE, Seoul (KR); HyeMi LEE, Paju-si (KR); KwangSu LIM, Seoul (KR); YoungIn JANG, Paju-si (KR); Soyoung LEE, Seoul (KR)

(73) Assignee: LG Display Co., Ltd., Seoul (KR)

(21) Appl. No.: 19/642,314

(22) Filed: Apr. 8, 2026

(30) Foreign Application Priority Data
Apr. 9, 2025 (KR) 10-2025-0046122

(51) Int. Cl. H10H 29/856; H10H 29/32; H10H 29/34; H10H 29/39; H10H 29/41; H10H 29/49; H10H 29/80

(52) U.S. Cl. CPC H10H 29/856; H10H 29/32; H10H 29/34; H10H 29/39; H10H 29/41; H10H 29/49; H10H 29/8325

(57) ABSTRACT

A display device can include a substrate on which a plurality of sub pixels and a plurality of contact areas between the plurality of sub pixels are disposed, light emitting elements disposed in the plurality of sub pixels, and a side reflection plate disposed in one of the plurality of sub pixels and adjacent to the light emitting elements. The display device can further include a first connection electrode electrically connected to a first electrode of the light emitting element, a planarization layer pattern covering the first connection electrode and the light emitting element, and a second connection electrode disposed on the planarization layer pattern. Accordingly, a short circuit defect of the first connection electrode and the second connection electrode can be prevented by the planarization layer pattern separating the first connection electrode and the second connection electrode.

### CROSS-REFERENCE TO RELATED APPLICATIONS

This application claims priority to Korean Patent Application No.10-2025-0046122 filed on Apr. 9, 2025, in the Ministry of Intellectual Property of the Republic of Korea, the entire disclosure of which is incorporated herein by reference.

### BACKGROUND

### FIELD

The present disclosure relates to a display device, and more particularly, to a display device using a light emitting diode (LED).

### DISCUSSION OF THE RELATED ART

Display devices can be used for a monitor of a computer, a TV, or a mobile phone, and various display devices can include an organic light emitting display (OLED) that can self-emits light, and a liquid crystal display (LCD) that requires a separate light source to emit light.

Nowadays, display devices have been applied in a variety of applications, including for computer monitors and TVs as well as personal portable devices, and research is continuing on display devices that have a large display area and yet have a reduced volume and weight to improve performances of the display devices.

In this light of improving the performances of the display devices, a display device including a light emitting diode (LED) is gaining attention as a next-generation display device. Display devices with the LED can be made of an inorganic material rather than an organic material, can have improved reliability, and a longer lifespan a liquid crystal display device or an organic light emitting display device. Further, the display device with the LED can have a fast light emitting speed, improved luminous efficiency, and a strong impact resistance so that reliability is improved and can display an image with high luminance.

### SUMMARY OF THE DISCLOSURE

An object to be achieved by the present disclosure is to provide a display device in which light extraction efficiency and luminance uniformity according to a viewing angle are improved.

Another object to be achieved by the present disclosure is to provide a display device in which an electrode of a light emitting element and a connection electrode are self-aligned.

Still another object to be achieved by the present disclosure is to provide a display device in which floating of a side reflection plate is prevented.

Still another object to be achieved by the present disclosure is to provide a display device which suppresses a short circuit defect of a first connection electrode and a second connection electrode with various insulating layers.

Still another object to be achieved by the present disclosure is to provide a display device capable of direct contact inspection of a light emitting element.

Still another object to be achieved by the present disclosure is to provide a display device in which a pad for inspecting a light emitting element is embedded.

Objects of the present disclosure are not limited to the above-mentioned objects, and other objects, which are not mentioned above, can be clearly understood by those skilled in the art from the following descriptions.

According to an embodiment of the present disclosure, a display device includes a substrate on which a plurality of sub pixels and a plurality of contact areas between the plurality of sub pixels are defined, light emitting elements disposed in each of the plurality of sub pixels, a side reflection plate disposed in each of the plurality of sub pixels and surrounding the light emitting elements, a first connection electrode electrically connected to a first electrode of the light emitting element, a planarization layer pattern covering the first connection electrode and the light emitting element, and a second connection electrode disposed on the planarization layer pattern, in which the first connection electrode and the second connection electrode are spaced apart from each other with the planarization layer pattern therebetween. Accordingly, a short circuit defect of the first connection electrode and the second connection electrode can be prevented by the planarization layer pattern separating the first connection electrode and the second connection electrode.

Other detailed matters of the embodiments are included in the detailed description and the drawings.

According to the present disclosure, it is possible to improve the light extraction efficiency of the light emitting element by forming a side reflection plate.

According to the present disclosure, luminance uniformity according to a viewing angle can be improved.

According to the present disclosure, it is possible to prevent a defect caused by static electricity by preventing the side reflection plate from floating.

According to the present disclosure, it is possible to prevent a short circuit defect of the first connection electrode and the second connection electrode.

According to the present disclosure, the electrode of the light emitting device and the connection electrode can be self-aligned.

According to the present disclosure, a light emitting test can be performed by directly applying an inspection signal to the light emitting element.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic configuration diagram of a display device according to an example embodiment of the present disclosure.

FIG. 2 is a partial cross-sectional view of a display device according to an example embodiment of the present disclosure.

FIG. 3 is a schematic enlarged plan view of a display area of a display device according to an example embodiment of the present disclosure.

FIG. 4 is a schematic enlarged plan view of a display area of a display device according to an example embodiment of the present disclosure.

FIG. 5 is a cross-sectional view of a display device taken along line A-A' in FIG. 3.

FIG. 6A is an enlarged cross-sectional view of an area X of FIG. 5.

FIG. 6B is a graph for explaining a luminance depending on a viewing angle of a light emitting element.

FIG. 6C is an example cross-sectional view of a second planarization layer and a third planarization layer of a display device according to an example embodiment of the present disclosure.

FIG. 7 is a schematic enlarged plan view of a display area of a display device according to another example embodiment of the present disclosure.

FIG. 8 is a cross-sectional view of a display device taken along line B-B' in FIG. 7.

FIG. 9 is a cross-sectional view of a display device according to still another example embodiment of the present disclosure.

FIG. 10 is a cross-sectional view of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise. Further, the term "can" encompasses all the meanings and coverages of the term "may" and vice versa.

Components are interpreted to include an ordinary error range even if not expressly stated.

When the position relation between two parts is described using the terms such as “on”, “above”, “below”, and “next to”, one or more parts can be positioned between the two parts unless the terms are used with the term “immediately” or “directly”.

When an element or layer is disposed “on” another element or layer, it can be directly on the another element or layer, or indirectly on the another element or layer with an intervening element or layer therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Further, the term “can” fully encompasses all the meanings and coverages of the term “may” and vice versa.

Hereinafter, the present disclosure will be described in detail with reference to the drawings.

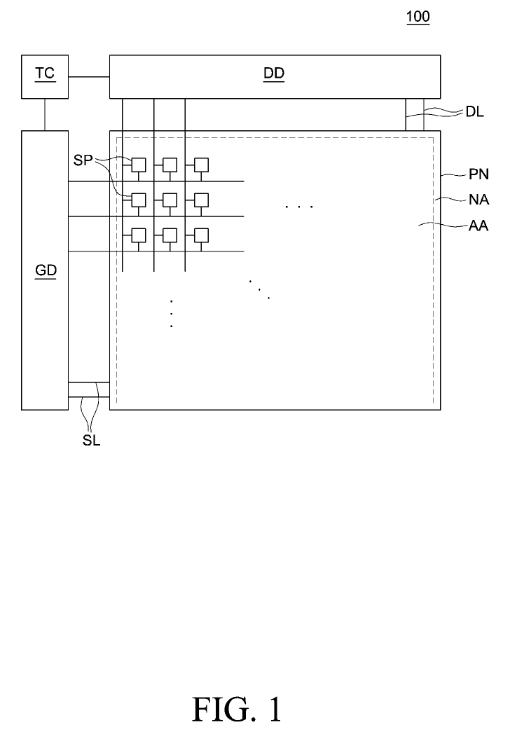

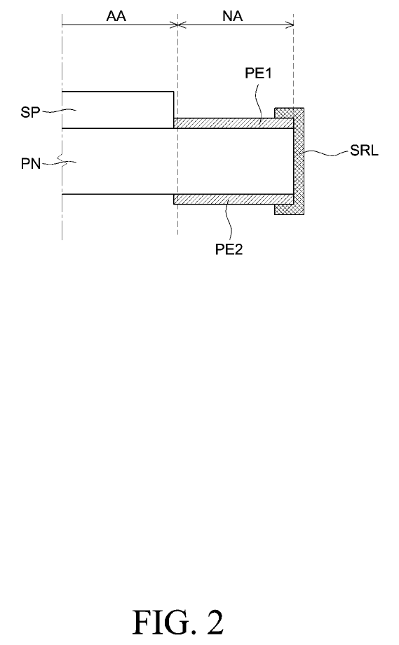

FIG. 1 is a schematic configuration diagram of a display device according to an example embodiment of the present disclosure. FIG. 2 is a partial cross-sectional view of a display device according to an example embodiment of the present disclosure. All components of each light emitting display apparatus according to all embodiments of the present disclosure are operatively coupled and configured. In FIG. 1, for the convenience of description, among various components of the display device 100, only a display panel PN, a gate driver GD, a data driver DD, and a timing controller TC are illustrated, but the display device 100 is not limited thereto.

Referring to FIG. 1, a display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals provided from the timing controller TC. FIG. 1 illustrates that one gate driver GD is disposed to be spaced apart from one side of the display panel PN. However, the number and arrangement of the gate drivers GD are not limited thereto.

The data driver DD supplies a data voltage to a plurality of data lines DL according to a plurality of data control signals and image data provided from the timing controller TC. The data driver DD can convert image data into a data voltage using a reference gamma voltage and supply the converted data voltage to a plurality of data lines DL.

The timing controller TC aligns image data input from the outside and supplies the image data to the data driver DD. The timing controller TC can generate a gate control signal and a data control signal by using a synchronization signal input from the outside, for example, a dot clock signal, a data enable signal, and a horizontal/vertical synchronization signal. Further, the timing controller TC supplies the generated gate control signal and data control signal to the gate driver GD and the data driver DD, respectively, to control the gate driver GD and the data driver DD, but is not limited thereto.

The display panel PN is configured to display images to a user and includes a plurality of sub pixels SP. In the display panel PN, the plurality of scan lines SL and the plurality of data lines DL can cross each other, and the plurality of sub pixels SP can be formed at intersections of the scan line SL and the data line DL.

In the display panel PN, a display area AA and a non-display area NA can be defined.

The display area AA is an area in which images are displayed in the display device 100. In the display area AA, a plurality of sub pixels SP constituting a plurality of pixels PX and a pixel circuit for driving the plurality of sub pixels SP can be disposed. The plurality of sub pixels SP is a minimum unit constituting the display area AA, and n sub pixels SP can form one pixel PX. A pixel circuit for driving the plurality of light emitting elements LED can be disposed in each of the plurality of sub pixels SP. The plurality of light emitting elements LED can be differently defined depending on the type of the display panel PN. For example, when the display panel PN is an inorganic light emitting display panel PN, the light emitting element LED can be a light emitting diode (LED) or a micro light emitting diode (micro-LED), but is not limited thereto.

In the display area AA, a plurality of signal lines for transmitting various signals to the plurality of sub pixels SP is disposed. For example, the plurality of signal lines can include a plurality of data lines DL which supplies a data voltage to each of the plurality of sub pixels SP, a plurality of scan lines SL which supplies a scan signal to each of the plurality of sub pixels SP, and the like. The plurality of scan lines SL can extend in one direction in the display area AA and be connected to the plurality of sub pixels SP, and the plurality of data lines DL can extend in a direction different from the one direction in the display area AA and be connected to the plurality of sub pixels SP. In addition, a power line, a reference line, and the like can be further disposed in the display area AA, but are not limited thereto.

The non-display area NA is an area where an image is not displayed and can be defined as an area extending from the display area AA. In the non-display area NA, a link line and a pad electrode for transmitting a signal to the sub pixel SP of the display area AA, or a driver IC, such as a gate driver IC or a data driver IC, can be disposed. The non-display area NA can be located on a rear surface of the display panel PN, for example, a surface on which the sub pixels SP are not disposed or can be omitted, and is not limited as illustrated in the drawing.

Meanwhile, a driver such as a gate driver GD, a data driver DD, and a timing controller TC can be connected to the display panel PN in various ways. For example, the gate driver GD can be mounted in the non-display area NA in a gate-in-panel (GIP) manner or mounted between the plurality of sub pixels SP in the display area AA in a gate-in-active area (GIA) manner, but is not limited thereto.

For example, the data driver DD and the timing controller TC can be formed on a separate flexible film and the printed circuit board. Further, the display panel PN, the data driver DD, and the timing controller TC can be electrically connected by bonding the flexible film and the printed circuit board to the pad electrode formed in the non-display area NA of the display panel PN, but is not limited thereto.

As another example, when the gate driver GD is mounted in the display area AA in the GIA manner, the flexible film and the printed circuit board can be bonded to the rear surface of the display panel PN and a side line SRL which connects the signal line on the front surface of the display panel PN to the pad electrode on the rear surface of the display panel PN is formed. Therefore, the non-display area NA can be minimized on the front surface of the display panel PN. Therefore, when the gate driver GD, the data driver DD, and the timing controller TC are connected to the display panel PN in the above-described manner, a zero bezel with substantially no bezel can be implemented.

In the non-display area NA of the display panel PN, a plurality of pad electrodes for transmitting various signals to the plurality of sub pixels SP is disposed. For example, a first pad electrode PE1 for transmitting a signal to the plurality of sub pixels SP is disposed in the non-display area NA on the front surface of the display panel PN, and a second pad electrode PE2 electrically connected to a driving component such as a flexible film and the printed circuit board is disposed in the non-display area NA on the rear surface of the display panel PN, but is not limited thereto.

In this case, various signal lines connected to the plurality of sub pixels SP, for example, a scan line SL or a data line DL extend from the display area AA to the non-display area NA to be electrically connected to the first pad electrode PE1, but is not limited thereto.

Further, the side line SRL is disposed along the side surface of the display panel PN. The side line SRL can electrically connect the first pad electrode PE1 on the front surface of the display panel PN and the second pad electrode PE2 on the rear surface of the display panel PN. Therefore, a signal from the driving component on the rear surface of the display panel PN can be transmitted to the plurality of sub pixels SP through the second pad electrode PE2, the side line SRL, and the first pad electrode PE1. Accordingly, a signal transmission path is formed from the front surface to the side surface and the rear surface of the display panel PN to minimize an area of the non-display area NA on the front surface of the display panel PN.

Accordingly, the driving component is connected to the rear surface of the display panel PN using the side line SRL to reduce the area of the non-display area NA and implement the display device 100 with a minimized bezel. Further, when a plurality of display devices 100 with a minimized bezel is arranged to form a tiling display device 100, a seam area between the two adjacent display device 100 in which an image is not displayed is minimized to improve display quality.

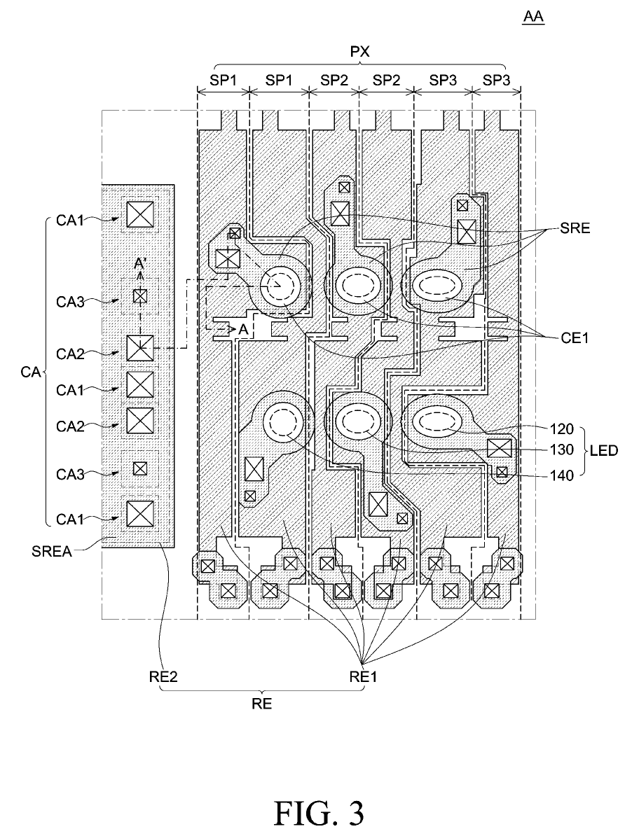

Hereinafter, a sub pixel SP of the display device 100 according to an example embodiment of the present disclosure will be described in more detail with reference to FIGS. 3-6C.

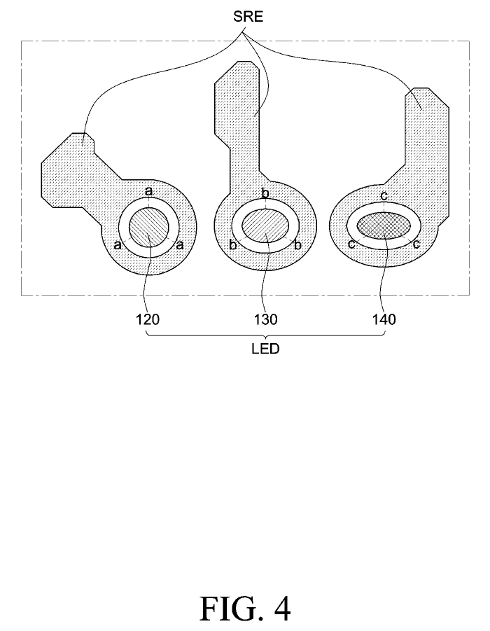

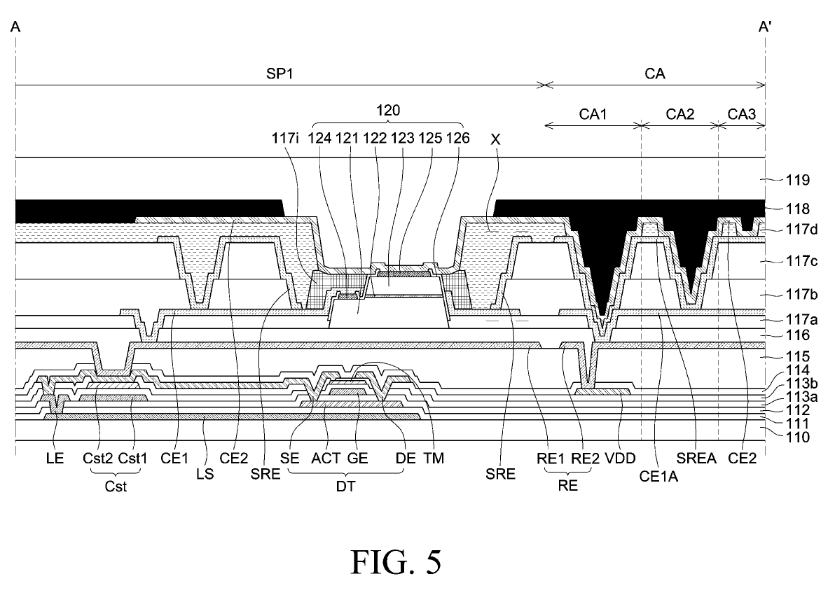

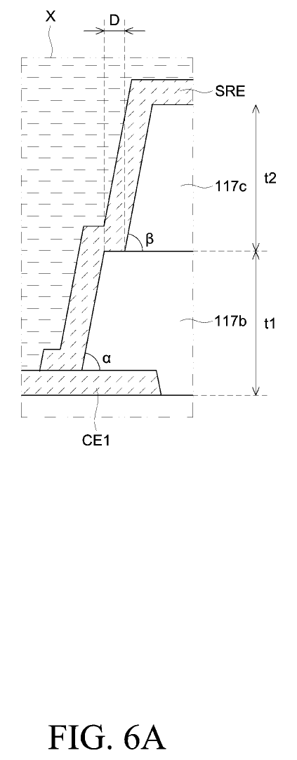

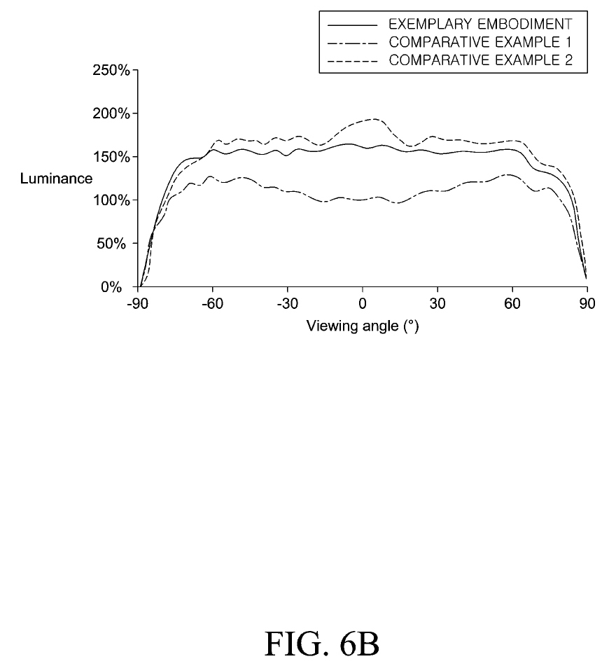

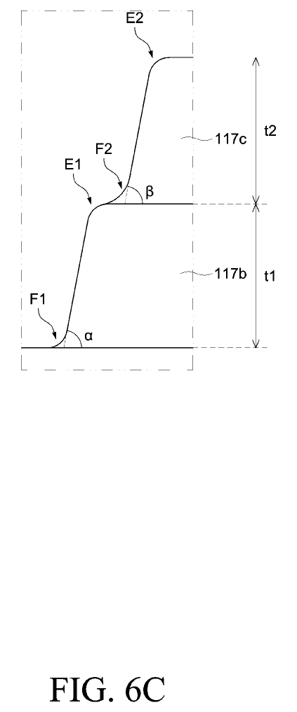

FIG. 3 is a schematic enlarged plan view of a display area of a display device according to an example embodiment of the present disclosure. FIG. 4 is a schematic enlarged plan view of a display area of a display device according to an example embodiment of the present disclosure. FIG. 5 is a cross-sectional view of a display device taken along line A-A' in FIG. 3. FIG. 6A is an enlarged cross-sectional view of an area X of FIG. 5. FIG. 6B is a graph for explaining a luminance depending on a viewing angle of a light emitting element. FIG. 6C is an example cross-sectional view of a second planarization layer and a third planarization layer of a display device according to an example embodiment of the present disclosure.

Referring to FIGS. 3-5, a pixel PX including a plurality of sub pixels SP is disposed in the display area AA. Each of the plurality of sub pixels SP includes a light emitting element LED and can independently emit light. The plurality of sub pixels SP can be disposed in a matrix while forming a plurality of rows and a plurality of columns, but the example embodiments of the present disclosure are not limited thereto.

The plurality of sub pixels SP includes a first sub pixel SP1, a second sub pixel SP2, and a third sub pixel SP3. For example, one or more first sub pixels SP1, one or more second sub pixels SP2, and one or more third sub pixels SP3 can constitute one pixel PX. For example, any one of the first sub pixel SP1, the second sub pixel SP2, and the third sub pixel SP3 can be a red sub pixel, the other one can be a green sub pixel, and the rest can be a blue sub pixel, but it is not limited thereto.

The contact area CA is disposed in the display area AA. The contact area CA is an area in which the power line VDD and the second connection electrode CE2 are electrically connected to each other. The contact area CA can be disposed between the plurality of pixels PX. The contact area CA will be described in more detail later.

Referring to FIG. 5, a substrate 110 is a member which supports other components of the display device 100. For example, the substrate 110 can be made of glass, resin, or the like. Further, the substrate 110 can be made of polymer, plastic, or the like, and in some embodiments, the substrate 110 can be made of a plastic material having flexibility, but is not limited thereto.

The light shielding layer LS is disposed on the substrate 110 in each of the plurality of sub pixels SP. The light shielding layer LS blocks light incident onto an active layer ACT of a driving transistor DT to minimize a leakage current. The light shielding layer LS can be formed of an opaque conductive material such as copper (Cu), aluminum (Al), molybdenum (Mo), nickel (Ni), titanium (Ti), chromium (Cr), or an alloy thereof, but is not limited thereto.

A buffer layer 111 is disposed on the substrate 110 and the light shielding layer LS. The buffer layer 111 is disposed to cover one surface of the substrate 110 to reduce the penetration of moisture or impurities through the substrate 110. For example, the buffer layer 111 can be configured as a single layer or multilayer made of silicon oxide (SiOx) or silicon nitride (SiNx), but is not limited thereto.

The driving transistor DT is disposed on the buffer layer 111 in each of the plurality of sub pixels SP. The driving transistor DT includes an active layer ACT, a gate electrode GE, a source electrode SE, and a drain electrode DE. Meanwhile, other components, such as a switching transistor, a sensing transistor, an emission control transistor, and a storage capacitor Cst, can be additionally disposed in each of the plurality of sub pixels SP, in addition to the driving transistor DT.

The active layer ACT of the driving transistor DT is disposed on the buffer layer 111. The active layer ACT can be formed of a semiconductor material such as an oxide semiconductor, amorphous silicon, or polysilicon, but is not limited thereto.

The gate insulating layer 112 is disposed on the active layer ACT. The gate insulating layer 112 is an insulating layer which insulates the active layer ACT from the gate electrode GE. For example, the gate insulating layer 112 can be configured by a single layer or a multilayer of silicon oxide (SiOx) or silicon nitride (SiNx), but is not limited thereto. Other materials can be used.

The gate electrode GE is disposed on the gate insulating layer 112. The gate electrode GE can be disposed to overlap the active layer ACT. The gate electrode GE can include a conductive material such as copper (Cu), aluminum (Al), molybdenum (Mo), nickel (Ni), titanium (Ti), chromium (Cr), or an alloy thereof, but is not limited thereto.

The first interlayer insulating layer 113a and the second interlayer insulating layer 113b are disposed on the gate electrode GE. In the first interlayer insulating layer 113a and the second interlayer insulating layer 113b, a contact hole through which the source electrode SE and the drain electrode DE are connected to the active layer ACT is formed. The first interlayer insulating layer 113a and the second interlayer insulating layer 113b are insulating layers which protect components therebelow and can be configured by a single layer or a multilayer of silicon oxide (SiOx) or silicon nitride (SiNx), but are not limited thereto.

The source electrode SE and the drain electrode DE are disposed on the second interlayer insulating layer 113b. The source electrode SE and the drain electrode DE can be electrically connected to the active layer ACT through contact holes formed in the first interlayer insulating layer 113a, the second interlayer insulating layer 113b, and the gate insulating layer 112. The source electrode SE and the drain electrode DE can include a conductive material, such as copper (Cu), aluminum (Al), molybdenum (Mo), nickel (Ni), titanium (Ti), chrome (Cr), or an alloy thereof, but are not limited thereto.

An intermediate electrode TM is disposed on the first interlayer insulating layer 113a. The intermediate electrode TM can be disposed to overlap the gate electrode GE of the driving transistor DT with the first interlayer insulating layer 113a therebetween to form a capacitor together with the gate electrode GE of the driving transistor DT, but is not limited thereto.

The auxiliary electrode LE is disposed on the gate insulating layer 112. The auxiliary electrode LE is an electrode which electrically connects the light shielding layer LS below the buffer layer 111 to any one of the source electrode SE and the drain electrode DE of the driving transistor DT on the second interlayer insulating layer 113b. For example, the light shielding layer LS is electrically connected to any one of the source electrode SE or the drain electrode DE through the auxiliary electrode LE so as not to operate as a floating gate. Therefore, fluctuation of a threshold voltage of the driving transistor DT caused by the floated light shielding layer LS can be minimized, but is not limited thereto.

The capacitor Cst is disposed on the gate insulating layer 112. The capacitor Cst includes a first capacitor electrode Cst1 and a second capacitor electrode Cst2.

The first capacitor electrode Cst1 can be disposed on the gate insulating layer 112. The first capacitor electrode Cst1 can be disposed on the same layer as the gate electrode GE and can be formed of the same material, but is not limited thereto.

The second capacitor electrode Cst2 can be disposed on the first interlayer insulating layer 113a. The second capacitor electrode Cst2 can be disposed on the same layer as the intermediate electrode TM and can be formed of the same material. The second capacitor electrode Cst2 can be disposed to overlap the first capacitor electrode Cst1 with the first interlayer insulating layer 113a interposed therebetween. The second capacitor electrode Cst2 can be electrically connected to the source electrode SE of the driving transistor DT.

The power line VDD is disposed on the second interlayer insulating layer 113b. The power line VDD can drive the light emitting element LED together with the driving transistor DT. The power line VDD can include a conductive material such as copper (Cu), aluminum (Al), molybdenum (Mo), nickel (Ni), titanium (Ti), chrome (Cr), or an alloy thereof, but is not limited thereto.

The passivation layer 114 is disposed on the driving transistor DT and the power line VDD. The passivation layer 114 can protect the driving transistor DT and the power line VDD from impurities, moisture, or the like. For example, the passivation layer 114 can be configured as a single layer or multilayer made of silicon oxide (SiOx) or silicon nitride (SiNx). However, the present disclosure is not limited thereto. Other materials can be used.

The overcoating layer 115 is disposed on the passivation layer 114. The overcoating layer 115 can planarize an upper portion of the substrate 110 on which the driving transistor DT is disposed. The overcoating layer 115 can be configured by a single layer or a multilayer, and for example, and can be formed of photoresist or an acrylic organic material, but is not limited thereto.

A plurality of reflective electrodes RE is disposed on the overcoating layer 115. The plurality of reflective electrodes RE electrically connects the light emitting element LED to the power line VDD and the driving transistor DT and can serve as a reflective plate that reflects light emitted from the light emitting element LED to an upper portion of the light emitting element LED. The plurality of reflective electrodes RE is formed of a conductive material having excellent reflection characteristics to reflect light emitted from the light emitting element LED toward the upper portion of the light emitting element LED.

The plurality of reflective electrodes RE can include various conductive layers in consideration of light reflection efficiency and resistance. For example, the plurality of reflective electrodes RE can use an opaque conductive layer such as silver (Ag), aluminum (Al), molybdenum (Mo), titanium (Ti), or an alloy thereof and a transparent conductive layer such as indium tin oxide (ITO), but the structure and material of the reflective electrode RE are not limited thereto. Other structure or materials can be used.

The plurality of reflective electrodes RE includes a first reflective electrode RE1 and a second reflective electrode RE2.

The first reflective electrode RE1 can electrically connect the driving transistor DT and the light emitting element LED. The first reflective electrode RE1 can be electrically connected to the source electrode SE or the drain electrode DE of the driving transistor DT through a contact hole formed in the passivation layer 114 and the overcoating layer 115. Further, the first reflective electrode RE1 can be electrically connected to the first electrode 124 of the light emitting element LED through the first connection electrode CE1.

The second reflective electrode RE2 can electrically connect the power line VDD and the light emitting element LED. The second reflective electrode RE2 can be disposed in the contact area CA and connected to the power line VDD. The second reflective electrode RE2 can be electrically connected to the power line VDD through a contact hole formed in the passivation layer 114 and the overcoating layer 115. The second reflective electrode RE2 can be electrically connected to the second electrode 125 of the light emitting element LED through the second connection electrode CE2.

The adhesive layer 116 is disposed on the plurality of reflective electrodes RE. The adhesive layer 116 is formed on the front surface of the substrate 110 to fix the light emitting element LED disposed on the adhesive layer 116. The adhesive layer 116 can be made of a photocurable or thermosetting adhesive material that can be cured by light or heat. For example, the adhesive layer 116 can be formed of an acrylic material including a photoresist, but is not limited thereto.

The plurality of light emitting elements LED can be disposed in each of the plurality of sub pixels SP on the adhesive layer 116. The plurality of light emitting elements LED is an element which emits light by a current and can include a light emitting element LED which emits red light, green light, and blue light and can implement various colored light including white light by a combination thereof. For example, the plurality of light emitting elements LED can be a light emitting diode (LED) or a micro-LED, but is not limited thereto.

Referring to FIG. 5, the first light emitting element 120 can include a first semiconductor layer 121, an emission layer 122, a second semiconductor layer 123, a first electrode 124, a second electrode 125, and an insulating layer 126.

The first semiconductor layer 121 is disposed on the adhesive layer 116 and the second semiconductor layer 123 is disposed on the first semiconductor layer 121. The first semiconductor layer 121 and the second semiconductor layer 123 can be semiconductor layers doped with n-type and p-type impurities. For example, each of the first semiconductor layer 121 and the second semiconductor layer 123 can be layers doped with n-type and p-type impurities into a material such as gallium nitride (GaN), indium aluminum phosphide (InAlP), or gallium arsenide (GaAs). Further, the p-type impurity can be magnesium (Mg), zinc (Zn), beryllium (Be), and the like, and the n-type impurity can be silicon (Si), germanium (Ge), tin (Sn), and the like, but not limited thereto. Other materials can be used.

A portion of the first semiconductor layer 121 can be disposed to protrude outward from the second semiconductor layer 123. The top surface of the first semiconductor layer 121 can include a portion overlapping the second semiconductor layer 123 and a portion disposed outside the second semiconductor layer 123. The light emitting element LED can be a lateral light emitting element LED. However, the sizes and shapes of the first semiconductor layer 121 and the second semiconductor layer 123 can be variously modified, but are not limited thereto.

The emission layer 122 is disposed between the first semiconductor layer 121 and the second semiconductor layer 123. The emission layer 122 can receive holes and electrons from the first semiconductor layer 121 and the second semiconductor layer 123 to emit light. The emission layer 122 can be formed by a single layer or a multi-quantum well (MQW) structure, and for example, can be formed of indium gallium nitride (InGaN) or gallium nitride (GaN), but is not limited thereto. Other materials can be used.

One or more first electrodes 124 can be disposed on the first semiconductor layer 121. The first electrode 124 is an electrode for electrically connecting the driving transistor DT and the first semiconductor layer 121. In this case, the first semiconductor layer 121 can be a semiconductor layer doped with an n-type impurity, and the first electrode 124 can be a cathode. The first electrode 124 can be disposed on a top surface of the first semiconductor layer 121 exposed from the emission layer 122 and the second semiconductor layer 123. The first electrode 124 can include a conductive material, for example, a transparent conductive material, such as indium tin oxide (ITO) or indium zinc oxide (IZO) or an opaque conductive material, such as titanium (Ti), gold (Au), silver (Ag), and copper (Cu), but is not limited thereto. Other materials can be used.

The second electrode 125 is disposed on the top surface of the second semiconductor layer 123. The second electrode 125 is an electrode for electrically connecting the power line VDD and the second semiconductor layer 123. Since the second semiconductor layer 123 is disposed on the first semiconductor layer 121, the second electrode 125 disposed on the top surface of the second semiconductor layer 123 can be disposed at a higher position than the first electrode 124. In this case, the second semiconductor layer 123 can be a semiconductor layer doped with a p-type impurity, and the second electrode 125 can be an anode. The second electrode 125 can include a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto. Other materials can be used.

Next, an insulating layer 126 can be disposed to surround the first semiconductor layer 121, the emission layer 122, the second semiconductor layer 123, the first electrode 124, and the second electrode 125. The insulating layer 126 can be formed of an insulating material to protect the first semiconductor layer 121, the emission layer 122, and the second semiconductor layer 123. Further, a contact hole which exposes the first electrode 124 and the second electrode 125 is formed in the insulating layer 126 to electrically connect the first connection electrode CE1 and the second connection electrode CE2 to be formed later, and the first electrode 124 and the second electrode 125.

Meanwhile, the second light emitting element 130 and the third light emitting element 140 can have the same configuration as the first light emitting element 120. For example, the second light emitting element 130 and the third light emitting element 140 can also include the same configuration as the first semiconductor layer 121, the emission layer 122, the second semiconductor layer 123, one or more first electrodes 124, the second electrode 125, and the insulating layer 126 of the first light emitting element 120, but is not limited thereto.

In this case, the second light emitting element 130 and the third light emitting element 140 have the same configuration as the first light emitting element 120, but can have different shapes to distinguish the first light emitting element 120, the second light emitting element 130, and the third light emitting element 140. For example, a planar shape of the first light emitting element 120 can be a circular shape, a planar shape of the second light emitting element 130 can be an oval shape, and a planar shape of the third light emitting element 140 can be an oval shape having a longer major axis than the second light emitting element 130, but is not limited thereto.

According to example embodiments of the present disclosure, a planarization structure can be included, which can include one or more of a first planarization layer 117a, a second planarization layer 117b, a third planarization layer 117c, a fourth planarization layer 117d, a planarization layer pattern 117i, but are not limited thereto. Different layers, additional layers or less layers can be provided. In example embodiments of the present disclosure, the planarization layer pattern 117i can include a first planarization layer pattern 117ia and a second planarization layer pattern 117ib, but is not limited thereto. Different patterns, additional patterns or less patterns can be provided, The first planarization layer 117a is disposed on the adhesive layer 116. The first planarization layer 117a is disposed so as to enclose a part of lower side surfaces of the plurality of light emitting elements LED to fix and protect the plurality of light emitting elements LED. The first planarization layer 117a can be configured by a single layer or a multilayer, and for example, can be formed of photoresist or an acrylic organic material, but is not limited thereto.

The first planarization layer 117a is disposed to surround the insulating layer 126 disposed at the lower edge of the light emitting element LED to suppress the disconnection of the first connection electrode CE1 due to the torn insulating layer 126. For example, during the process of separating the wafer and the light emitting element LED, a part of the insulating layer 126 can be torn off at the lower edge of the light emitting element LED. Accordingly, a portion of the first semiconductor layer 121 at the lower edge of the light emitting element LED can be exposed from the insulating layer 126. In this case, when the first connection electrode CE1 is disposed to surround the side surface of the insulating layer 126, the first connection electrode CE1 can be disconnected due to a step caused by the torn insulating layer 126. Accordingly, before the first connection electrode CE1 is formed, the first planarization layer 117a is disposed to surround the lower edge of the light emitting element LED to separate the lower edge of the light emitting element LED from the first connection electrode CE1. Even if an undercut structure due to the torn insulating layer 126 is formed on the lower edge of the light emitting element LED, the first planarization layer 117a is in contact with at least a part of the side surface of the light emitting element LED to fill the undercut structure, thereby minimizing the short circuit of the first connection electrode CE1 due to the undercut structure.

Next, the first connection electrode CE1 is disposed on the first planarization layer 117a in each of the plurality of sub pixels SP. The first connection electrode CE1 is an electrode for electrically connecting the light emitting element LED and the driving transistor DT. The first connection electrode CE1 can be connected to the first reflective electrode RE1 through a contact hole formed in the first planarization layer 117a and the adhesive layer 116. The first connection electrode CE1 can be electrically connected to any one of the source electrode SE and the drain electrode DE of the driving transistor DT through the first reflective electrode RE1. Further, the first connection electrode CE1 is disposed so as to cover the side surface portion of the light emitting element LED and the first electrode 124 to be electrically connected to the first electrode 124. For example, the first connection electrode CE1 can be formed of a transparent conductive material, such as indium tin oxide (ITO) or indium zinc oxide (IZO), but is not limited thereto. Other materials can be used.

The second planarization layer 117b is disposed on the first planarization layer 117a, the first connection electrode CE1, and the first contact electrode CE1A, and the third planarization layer 117c is disposed on the second planarization layer 117b. The second planarization layer 117b and the third planarization layer 117c can planarize an upper portion of the substrate 110 on which the light emitting element LED is disposed together with the first planarization layer 117a. The second planarization layer 117b and the third planarization layer 117c can be configured by a single layer or a multilayer, and for example, can be formed of photoresist or an acrylic organic material, but is not limited thereto. Other materials can be used.

An opening overlapping each of the plurality of light emitting elements LED can be formed in the second planarization layer 117b and the third planarization layer 117c. A side surface of the second planarization layer 117b and a side surface of the third planarization layer 117c can be disposed to be spaced apart from the light emitting element LED in the opening. The opening can have a planar shape corresponding to a planar shape of the light emitting element LED. A distance from a side surface of the second planarization layer 117b and a side surface of the third planarization layer 117c forming the opening to the light emitting element LED can be constant. The side surface of the second planarization layer 117b and the side surface of the third planarization layer 117c of the opening which faces the light emitting element LED can provide an inclined surface on which the side reflection plate SRE is disposed. The side surfaces of the second planarization layer 117b and the third planarization layer 117c can be inclined, but is not limited thereto.

Next, the planarization layer pattern 117i which is disposed on the first connection electrode CE1 and encloses the light emitting element LED is disposed. The planarization layer pattern 117i is disposed so as to enclose a part of the first connection electrode CE1 which covers the light emitting element LED and an upper portion of the light emitting element LED. The uppermost second electrode 125 of the light emitting element LED can be exposed from the planarization layer pattern 117i. The planarization layer pattern 117i disposed to cover the first connection electrode CE1 can separate the first connection electrode CE1 and the second connection electrode CE2 and suppress a short circuit defect of the first connection electrode CE1 and the second connection electrode CE2.

The planarization layer pattern 117i can be formed from any one of the second planarization layer 117b and the third planarization layer 117c. For example, the planarization layer pattern 117i can be formed together when the second planarization layer 117b is formed or can be formed together when the third planarization layer 117c is formed, but is not limited thereto.

The side reflection plate SRE is disposed on the third planarization layer 117c in each of the plurality of sub pixels SP. The side reflection plate SRE can reflect light, which is directed in a lateral direction, toward the upper side of the substrate 110 among light emitted from the light emitting element LED. The side reflection plate SRE is disposed in a side area of the light emitting element LED. The side reflection plate SRE can be disposed on a side surface of the second planarization layer 117b and a side surface of the third planarization layer 117c facing the light emitting element LED.

The side reflection plate SRE can be electrically connected to the first connection electrode CE1 through contact holes of the second planarization layer 117b and the third planarization layer 117c. The side reflection plate SRE is connected to the first connection electrode CE1 to avoid a floating state therebetween, and prevent static electricity or the like that can be generated in the floating state. For example, the side reflection plate SRE can include a conductive material having excellent reflection characteristics, such as silver (Ag), aluminum (Al), molybdenum (Mo), titanium (Ti), or an alloy thereof, with high reflection efficiency, but the configuration of the side reflection plate SRE is not limited thereto.

Referring to FIGS. 4 and 5, the side reflection plate SRE is disposed to surround each of the plurality of light emitting elements LED and the side reflection plate SRE has an opening overlapping the plurality of light emitting elements LED. The planar shape of the opening of the side reflection plate SRE can correspond to a planar shape of the light emitting element LED. Accordingly, in a planar view, the distance from the side reflection plate SRE to the light emitting element LED can be configured at equal intervals.

For example, the side reflection plate SRE of the first sub pixel SP1 can have a circular opening corresponding to a planar shape of the first light emitting element 120, the side reflection plate SRE of the second sub pixel SP2 can have an opening having an oval shape corresponding to a planar shape of the second light emitting element 130, and the side reflection plate SRE of the third sub pixel SP3 can have an opening having an oval shape corresponding to a planar shape of the third light emitting element 140. Further, an interval between the first light emitting element 120 and the side reflection plate SRE can be equal to a, an interval between the second light emitting element 130 and the side reflection plate SRE can be equal to b, and an interval between the third light emitting element 140 and the side reflection plate SRE can be equal to c. In an example, the values of a, b and c can be different from each other, but the disclosure is not limited thereto. Accordingly, the interval between the side reflection plate SRE and the light emitting element LED can be constant or can be constantly configured, such that the improvement of the light efficiency by the side reflection plate SRE can be performed at the same level at all angles. Further, the light reflected from the side reflection plate SRE is collected toward the light emitting element LED and the center of the opening of the side reflection plate SRE to further improve the center luminance of the emission area.

A fourth planarization layer 117d is disposed on the side reflection plate SRE and the second contact electrode SREA. An opening overlapping the light emitting element LED and the planarization layer pattern 117i can be formed in the fourth planarization layer 117d. The planarization layer pattern 117i and the second electrode 125 of the light emitting element LED can be exposed through the opening of the fourth planarization layer 117d. The fourth planarization layer 117d can be configured as a single layer or multilayer and made of, for example, photoresist or an acrylic-based organic material, but is not limited thereto.

The second connection electrode CE2 is disposed on the fourth planarization layer 117d. The second connection electrode CE2 is an electrode for electrically connecting the light emitting element LED and the power line VDD. The second connection electrode CE2 can be electrically connected to the power line VDD through the first contact electrode CE1A, the second contact electrode SREA, and the second reflective electrode RE2 of the contact area CA. The second connection electrode CE2 can be electrically connected to the second electrode 125 of the light emitting element LED through the opening of the fourth planarization layer 117d. For example, the second connection electrode CE2 can be formed of a transparent conductive material, such as indium tin oxide (ITO) or indium zinc oxide (IZO), but is not limited thereto.

Meanwhile, the planarization layer pattern 117i can guide the second connection electrode CE2 to be self-aligned to the second electrode 125 of the light emitting element LED. Since only the second electrode 125 of the light emitting element LED is exposed from the fourth planarization layer 117d and the planarization layer pattern 117i in the areas of the plurality of sub pixels SP, the second connection electrode CE2 is formed in the entire sub pixel SP area to connect the second electrode 125 and the second connection electrode CE2 to each other. Accordingly, it is not necessary to precisely align the light emitting element LED and the second electrode 125 and in a state in which only the second electrode 125 is exposed from the planarization layer pattern 117i in advance, the second connection electrode CE2 covering the upper portion of the light emitting element LED is formed to allow the second electrode 125 and the second connection electrode CE2 to be self-aligned.

Next, the first contact electrode CE1A is disposed on the first planarization layer 117a in the contact area CA. The first contact electrode CE1A is an electrode for electrically connecting the light emitting element LED and the power line VDD. For example, in the first contact area CA1, the first contact electrode CE1A can be electrically connected to the second reflective electrode RE2 through contact holes formed in the first planarization layer 117a and the adhesive layer 116. In each of the first contact area CA1 and the second contact area CA2, the first contact electrode CE1A can be electrically connected to the second contact electrode SREA, but is not limited thereto.

The first contact electrode CE1A can be disposed on the same layer and made of the same material as the first connection electrode CE1, but is not limited thereto. For example, the first contact electrode CE1A can be formed of a transparent conductive material, such as indium tin oxide (ITO) or indium zinc oxide (IZO), but is not limited thereto.

The second contact electrode SREA is disposed on the third planarization layer 117c in the contact area CA. The second contact electrode SREA is an electrode which electrically connects the light emitting element LED and the power line VDD together with the first contact electrode CE1A. For example, in each of the first contact area CA1 and the second contact area CA2, the second contact electrode SREA can be connected to the first contact electrode CE1A through contact holes formed in the second planarization layer 117b and the third planarization layer 117c. In the first contact area CA1, the second contact area CA2 and the third contact area CA3, the second contact electrode SREA can be electrically connected to the second connection electrode CE2 through the contact hole of the fourth planarization layer 117d, but is not limited thereto.

The second contact electrode SREA can be formed of the same material on the same layer as the side reflection plate SRE. For example, the second contact electrode SREA can be formed of a conductive material having excellent reflective properties, such as silver (Ag), aluminum (Al), molybdenum (Mo), titanium (Ti), or an alloy thereof, but is not limited thereto.

Further, the power line VDD can be electrically connected to the second connection electrode CE2 through the plurality of contact electrodes and the second reflective electrode RE2 in each of the plurality of contact areas CA. Accordingly, the resistance between the power line VDD and the second connection electrode CE2 can be reduced due to the plurality of contact structures, and the stability of the electrical connection can be improved.

For example, the second connection electrode CE2 can be disposed to extend from the plurality of sub pixels SP to the contact area CA. The second connection electrode CE2 can be electrically connected to the second reflective electrode RE2 and the power line VDD through a plurality of contact electrodes in the contact area CA. Specifically, in the first contact area CA1, the second connection electrode CE2, the second contact electrode SREA, the first contact electrode CE1A, the second reflective electrode RE2, and the power line VDD can be electrically connected to each other. In the second contact area CA2, the second connection electrode CE2, the second contact electrode SREA, and the first contact electrode CE1A can be electrically connected to each other. Finally, in the third contact area CA3, the second connection electrode CE2 and the second contact electrode SREA can be electrically connected to each other.

Therefore, even though a connection failure or the like occurs in some contact areas CA, the power line VDD and the second connection electrode CE2 can be electrically connected to each other through the remaining contact areas CA. Further, the second connection electrode CE2 is in contact with the plurality of contact electrodes in the plurality of contact areas CA so that the resistance of the second connection electrode CE2 can be reduced.

Next, the bank 118 is disposed on the second connection electrode CE2 and the fourth planarization layer 117d. The bank 118 can be disposed in the remaining area excluding the area in which the plurality of light emitting elements LED is disposed. An area exposed from the bank 118 can be defined as an emission area. For example, the bank 118 can cover an edge of the second connection electrode CE2 connected to each light emitting element LED to define an emission area. The bank 118 can include a black component having a high light absorption rate and can be configured as a black bank 118 to prevent color mixture between adjacent sub pixels SP. For example, the bank 118 can be formed of polyimide resin, acrylic resin, or benzocyclobutene (BCB) resin, but is not limited thereto.

A protective layer 119 is disposed on the bank 118. The protective layer 119 can be disposed on the entire surface of the substrate 110 to protect the components below the protective layer 119. The protective layer 119 can be referred to as a capping layer, but is not limited thereto. The protective layer 119 can be configured as a single layer or multilayer and made of, for example, a photoresist or an acrylic-based organic material, but is not limited thereto.

Meanwhile, in the display device 100 according to the example embodiment of the present disclosure, the angle of the side reflection plate SRE is determined by the angle of the side surface of the second planarization layer 117b and the angle of the side surface of the third planarization layer 117c. In this case, the luminance distribution according to the viewing angle can vary according to the angle of the side reflection plate SRE. In example embodiments of the present disclosure, the planarization layer pattern 117i can have a side surface that is angled or inclined, but is not limited thereto. For example, the side surface of the planarization layer pattern 117i can be aligned vertically. When the side surface of the planarization layer pattern 117i is angled or is vertical, an alignment of the side surface of the planarization layer pattern 117i can match that of a side surface of at least one of the first semiconductor layer 121 and the second semiconductor layer 123, but is not limited thereto. For example, the incline of the side surface of the planarization layer pattern 117i can be aligned or matched with the inclines and/or the angles of the side surfaces of the second planarization layer 117b and/or the third planarization layer 117c, but is not limited thereto.

Referring to FIG. 6A, in the display device 100 according to the embodiment of the present disclosure, the side surface of the second planarization layer 117b can have a first angle α, the side surface of the third planarization layer 117c can have a second angle β, and the first angle α and the second angle β can be an angle of 60 degrees or less. For example, the first angle α and the second angle β can be about 55 degrees, but is not limited thereto.

FIG. 6B is a graph measuring luminance distribution according to a viewing angle in each of example embodiment, Comparative Example 1 and Comparative Example 2. The example embodiment is a case in which the side reflection plate SRE has the same structure as the display device 100 according to the example embodiment of the present disclosure. Comparative Example 1 is a case in which the side reflection plate SRE does not exist in the display device 100 according to the example embodiment of the present disclosure. Comparative Example 2 is a case in which the first angle α and the second angle β on the side surfaces of the second planarization layer 117b and the third planarization layer 117c in which the side reflection plate SRE is disposed in the display device 100 according to the example embodiment of the present disclosure are 60 degrees or more. In the graph, the light emitting element LED is positioned at 0° and the luminance distribution from 0° to 90° above the light emitting element LED can be checked. At this time, the luminance is assumed to be 100% at the center of the light emitting element LED in Comparative Example 1, and the relative luminance distribution between Example embodiment and Comparative Example 2 was displayed.

First, in Comparative Example 1, the side reflection plate SRE is not present so that some light may not be collected toward the center of the light emitting element LED and can be directed toward the side surface direction of the light emitting element LED. Therefore, in Comparative Example 1, it can be seen that the luminance in the lateral direction is higher than the luminance in the upper portion of the light emitting element LED.

In the example embodiment, the side reflection plate SRE is disposed on the second planarization layer 117b and the third planarization layer 117c having side surfaces of the first angle α and the second angle β, and some light which is directed in the lateral direction, among light emitted from the light emitting element LED, can be collected toward the center of the light emitting element LED. Accordingly, in the example embodiment, it can be seen that the luminance above the light emitting element LED and the luminance in the lateral direction have an overall even distribution.

In Comparative Example 2, the side reflection plate SRE is present, but the side reflection plate SRE has a higher slope than in the example embodiment and more light directed to the lateral direction can be collected at the center of the light emitting element LED. Accordingly, the luminance of the upper portion of the light emitting element LED is increased compared to that of other viewing angle areas, so that a luminance deviation according to the viewing angle can occur.

Accordingly, in the display device 100 according to the example embodiment of the present disclosure, the first angle α of the side surface of the second planarization layer 117b in which the side reflection plate SRE is disposed and the second angle β of the side surface of the third planarization layer 117c are formed to be an angle of 60 degrees or less, for example, about 55 degrees, so that the luminance distribution according to the viewing angle can be uniformly formed.

Meanwhile, referring to FIG. 6A, the first angle α on the side surface of the second planarization layer 117b and the second angle β on the side surface of the third planarization layer 117c can be affected by thicknesses of the second planarization layer 117b and the third planarization layer 117c. For example, as the thicknesses of the second planarization layer 117b and the third planarization layer 117c increase, the slope of the side surface can be steeply formed, and as the thicknesses of the second planarization layer 117b and the third planarization layer 117c decrease, the slope of the side surface can be gently formed.

For example, the second planarization layer 117b can have a first thickness t1, and the third planarization layer 117c can have a second thickness t2. At this time, the first thickness t1 and the second thickness t2 are formed to have the same level, such that the first angle α of the side surface of the second planarization layer 117b and the second angle β of the side surface of the third planarization layer 117c can be implemented to have the same level.

Further, the third planarization layer 117c is formed on the top surface of the second planarization layer 117b to adjust the thickness of the third planarization layer 117c so as not to be excessively thick. In this case, a side surface of the third planarization layer 117c can be disposed on the top surface of the second planarization layer 117b, and a side surface of the second planarization layer 117b can be exposed from the third planarization layer 117c. A side surface of the third planarization layer 117c can be disposed to be spaced apart from a side surface of the second planarization layer 117b in consideration of an alignment error and a process margin. If the third planarization layer 117c is formed to cover all of the side surface of the second planarization layer 117b, the thickness of the third planarization layer 117c can increase, such that the inclination of the side surface of the third planarization layer 117c can be steeply formed, and the angle of the side reflection plate SRE can also increase. In this case, the luminance of the center of the light emitting element LED is increased more than that of other viewing angle areas so that the luminance distribution can be formed unevenly.

Therefore, the side surface of the third planarization layer 117c can be formed inside the top surface of the second planarization layer 117b so that the third planarization layer 117c does not have a thick thickness and a steep side surface by covering the side surface of the second planarization layer 117b. A side surface of the third planarization layer 117c and a side surface of the second planarization layer 117b can have an interval of D. The second planarization layer 117b and the third planarization layer 117c can be designed such that an interval between a side surface of the third planarization layer 117c and a side surface of the second planarization layer 117b is at least D in consideration of an alignment error and a process margin of each of the second planarization layer 117b and the third planarization layer 117c. In this case, the interval D can be greater than a margin of an alignment error generated during the exposure process of the second planarization layer 117b and the third planarization layer 117c. Accordingly, a side surface of the third planarization layer 117c facing the light emitting element LED is disposed on the second planarization layer 117b, and the second planarization layer 117b and the third planarization layer 117c can form a stepped structure.

Referring to FIG. 6C, edge portions of the second planarization layer 117b and the third planarization layer 117c can be formed to be curved according to a manufacturing process requirement or the like. For example, the second planarization layer 117b can include a first lower edge F1 between a bottom surface and a side surface and a first upper edge E1 between a top surface and a side surface. The first lower edge F1 and the first upper edge E1 can have an arc shape. The first lower edge F1 can have a concave arc-shaped surface, and the first upper edge E1 can have a convex arc-shaped surface. The third planarization layer 117c can include a second lower edge F2 between the bottom surface and the side surface and a second upper edge E2 between the top surface and the side surface. The second lower edge F2 and the second upper edge E2 can also have an arc shape. The second lower edge F2 can have a concave arc-shaped surface, and the second upper edge E2 can have a convex arc-shaped surface.

The second planarization layer 117b and the third planarization layer 117c have a stepped structure, but from the end of the arc of the first upper edge E1 of the second planarization layer 117b, the arc portion of the first upper edge E1 and the arc portion of the second lower edge F2 of the third planarization layer 117c can be continuously disposed without a stepped flat portion. The first upper edge E1 and the second lower edge F2 can be continuously disposed. The first upper edge E1 and the second lower edge F2 can form a stepped shape.

When the first thickness t1 of the second planarization layer 117b and the second thickness t2 of the third planarization layer 117c are the same, and the first angle α of the side surface of the second planarization layer 117b and the second angle β of the side surface of the third planarization layer 117c are the same, the first upper edge E1 of the second planarization layer 117b and the second upper edge E2 of the third planarization layer 117c can have the same curvature. For example, the first upper edge E1 and the second upper edge E2 can be formed in an arc shape of the same radius. Further, an arc of the first lower edge F1 of the second planarization layer 117b can have a smaller radius than an arc of the second lower edge F2 of the third planarization layer 117c. Accordingly, the curvature of the arc of the first lower edge F1 can be greater than the curvature of the arc of the second lower edge F2, and the degree of bending of the first lower edge F1 can be greater than the degree of bending of the second lower edge F2, but is not limited thereto.

The first lower edge F1 and the first upper edge E1 of the second planarization layer 117b and the second lower edge F2 and the second upper edge E2 of the third planarization layer 117c are formed to have a curved shape, such that a part of the side reflection plate SRE formed along the surfaces of the second planarization layer 117b and the third planarization layer 117c can be formed to have a curved shape. The side reflection plate SRE can be formed along the surface shapes of the second planarization layer 117b and the third planarization layer 117c, and a part of the side reflection plate SRE covering the first lower edge F1, the first upper edge E1, the second lower edge F2, and the second upper edge E2 can be formed in a curved shape. Therefore, at least a part of the side reflection plate SRE is formed as a curved surface to increase the reflection efficiency of the side reflection plate SRE, and accordingly, the luminance uniformity can also be improved.

Accordingly, in the display device 100 according to the example embodiment of the present disclosure, the side surface of the third planarization layer 117c is formed to have a stepped structure disposed on the top surface of the second planarization layer 117b, such that the thickness of the third planarization layer 117c is not excessively thick, and the side angle of the third planarization layer 117c can be easily adjusted. The angles of the side surfaces of the second planarization layer 117b and the third planarization layer 117c on which the side reflection plate SRE is disposed are formed within a target range to maximize the light extraction efficiency of the light emitting element LED by the side reflection plate SRE. For example, while the side surface of the third planarization layer 117c is disposed in the area on the second planarization layer 117b, the third planarization layer 117c is formed to have an interval of at least D from the side surface of the second planarization layer 117b, such that the second angle β of the side surface of the third planarization layer 117c can be easily formed to have a degree of about 55°, but is not limited thereto.

In addition, in the display device 100 according to the example embodiment of the present disclosure, the light emitting element LED is enclosed in each of the plurality of sub pixels SP and the side reflection plate SRE having an equal interval with the light emitting element LED is disposed to uniformly form a luminance distribution according to the viewing angle. Since the interval between the side reflection plate SRE and the light emitting element LED is constantly configured, the reflection of light emitted from the light emitting element LED is made at the same level at all angles, and the luminance uniformity according to the viewing angle can be improved. With reference to FIGS. 5-6C, thicknesses of the planarization layer pattern 117i can vary. For example, a portion of the planarization layer pattern 117i on the first semiconductor layer 121 can be less than a portion of planarization layer pattern 117i on the first planarization layer 117a, but is not limited thereto.

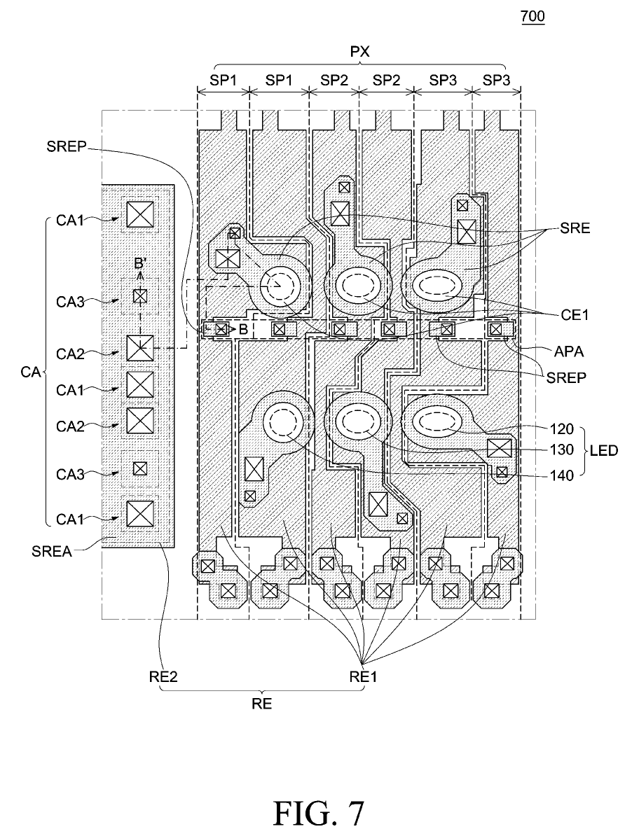

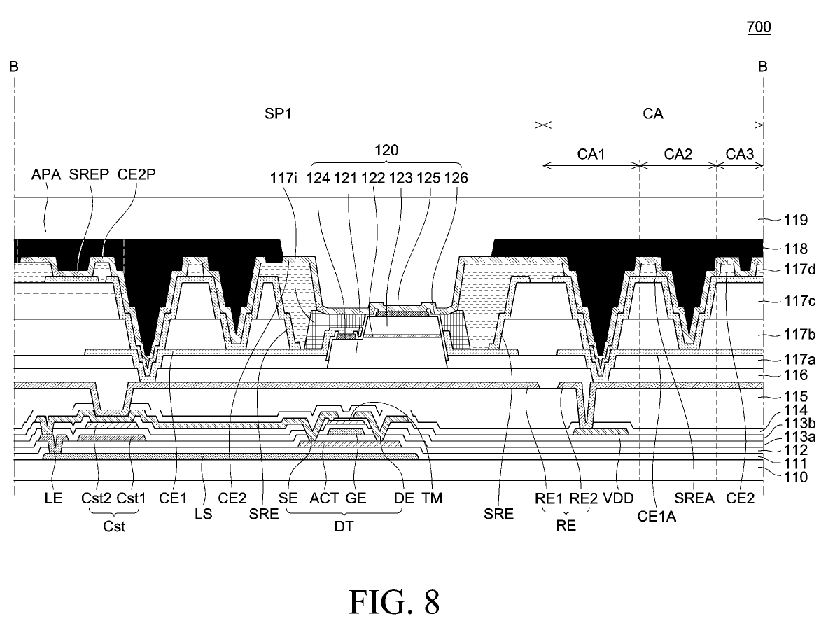

FIG. 7 is a schematic enlarged plan view of a display area of a display device according to another example embodiment of the present disclosure. FIG. 8 is a cross-sectional view of a display device taken along line B-B' in FIG. 7. A display device 700 of FIGS. 7 and 8 has the substantially same configuration as the display device 100 of FIGS. 1-5, except that an inspection area APA and an inspection pad are further included, so that a redundant description will be omitted.

Referring to FIGS. 7 and 8, the inspection area APA is formed in each of the plurality of sub pixels SP. The inspection area APA is an area in which inspection pads for light emitting inspection of the plurality of light emitting elements LED are disposed. The test signal can be directly applied to the light emitting element LED using the inspection pad of the test area APA without driving the driving transistor DT. For example, the inspection pad is a pad connected to the first connection electrode CE1, and an inspection signal can be applied to the first connection electrode CE1 and the first electrode 124 of the light emitting element LED through the inspection pad, but is not limited thereto.

The inspection pad includes a first inspection pad SREP and a second inspection pad CE2P. The first inspection pad SREP is disposed on the third planarization layer 117c, and the second inspection pad CE2P is disposed on the fourth planarization layer 117d. The first inspection pad SREP can be electrically connected to the side reflection plate SRE through the second inspection pad CE2P. The first inspection pad SREP and the second inspection pad CE2P can be electrically connected to the first connection electrode CE1 through the side reflection plate SRE. The second inspection pad CE2P can be electrically connected to the first inspection pad SREP and the side reflection plate SRE through a contact hole of the fourth planarization layer 117d. Therefore, the first inspection pad SREP and the second inspection pad CE2P can be electrically connected to the first electrode 124 of the light emitting element LED through the side reflection plate SRE and the first connection electrode CE1.

The first inspection pad SREP can be formed of the same material on the same layer as the side reflection plate SRE, and the second inspection pad CE2P can be formed of the same material on the same layer as the second connection electrode CE2.

The plurality of light emitting elements LED is transferred onto the adhesive layer 116, and a light emitting test can be performed after forming the first planarization layer 117a, the first connection electrode CE1, the second planarization layer 117b, the third planarization layer 117c, the side reflection plate SRE and the first inspection pad SREP, the fourth planarization layer 117d, the second connection electrode CE2, and the second inspection pad CE2P. When performing the light emitting test, the test signal can be directly applied to the second inspection pad CE2P of the test area APA to apply the test signal to the first electrode 124 of the light emitting element LED. Further, an inspection signal can be directly applied to the second connection electrode CE2 to apply an inspection signal to the second electrode 125 of the light emitting element LED. The light emitting element LED can emit light by an inspection signal applied to the first electrode 124 and the second electrode 125 and detect a defective light emitting element LED which does not emit light in the process. Finally, after the light emitting test is completed, the bank 118 and the protective layer 119 are formed on the inspection pad and the second connection electrode CE2 to complete the manufacturing process of the display device 700.

Accordingly, a signal is directly applied to the inspection pad and the second connection electrode CE2 to perform a light emitting test of the light emitting element LED before the bank 118 is formed. Further, without driving the driving transistor DT and the power line VDD, an inspection pad connected to the first electrode 124 and the second electrode 125 of the light emitting element LED and the probe pin are in contact with the second connection electrode CE2 to perform an illumination inspection of the light emitting element LED. If there is a defect in the pixel circuit including the driving transistor DT or the power line VDD, it can be difficult to normally inspect the light emitting element LED. Accordingly, an inspection signal is directly applied to the inspection pad and the second connection electrode CE2 separate from the driving transistor DT and the power line VDD to perform a light emitting inspection, thereby detecting a defect of the light emitting element LED at an early stage.

Next, the first connection electrode CE1 can be in contact with the side reflection plate SRE and the plurality of inspection pads at least once or more, thereby reducing the resistance of the first connection electrode CE1. For example, a plurality of contact holes are formed in the second planarization layer 117b and the third planarization layer 117c so that the first connection electrode CE1, the side reflection plate SRE, and the inspection pad can be in contact with each other a plurality of times, but is not limited thereto. Accordingly, the resistance of the first connection electrode CE1 can be reduced due to the plurality of contact structures, and the stability of the electrical connection can be improved.

Accordingly, in the display device 700 according to another example embodiment of the present disclosure, the inspection area APA is provided in each of the plurality of sub pixels SP to easily detect a defect of the light emitting element LED. An inspection pad directly connected to the first connection electrode CE1 connected to the first electrode 124 of the light emitting element LED is formed in the inspection area APA, and the second connection electrode CE2 connected to the second electrode 125 of the light emitting element LED is formed, and then the light emitting test can be performed. An inspection signal is directly applied to the inspection pad and the second connection electrode CE2 to apply the inspection signal to the first electrode 124 and the second electrode 125 of the light emitting element LED to detect a light emitting defect. In this case, since the test signal is not applied through the driving transistor DT, an inspection error due to a defect of the driving transistor DT can be prevented. Accordingly, the inspection area APA is embedded in each of the plurality of sub pixels SP to quickly and accurately detect a defect of the light emitting element LED.

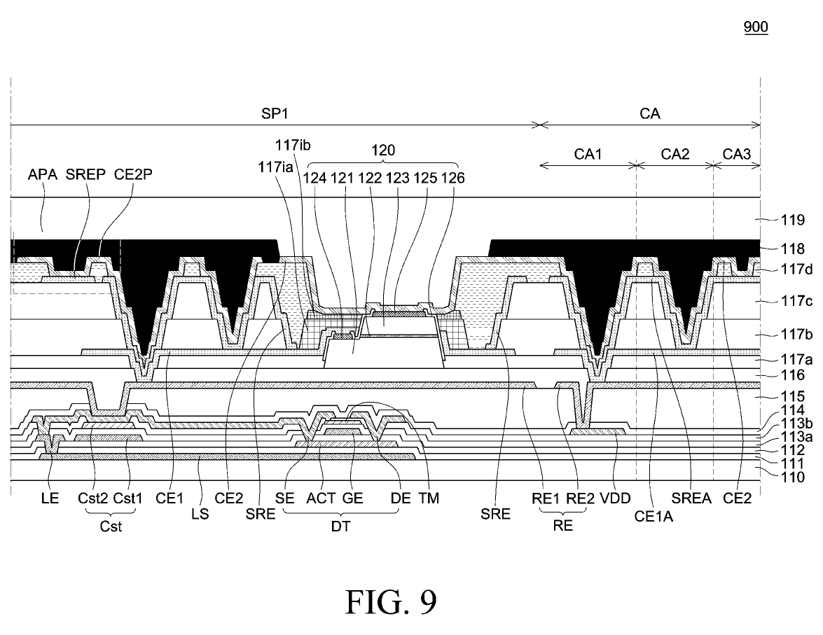

FIG. 9 is a cross-sectional view of a display device according to still another example embodiment of the present disclosure. A display device 900 of FIG. 9 is substantially identical in configuration to the display device 700 of FIGS. 7 and 8, except for planarization layer patterns 117ia and 117ib. Therefore, repeated descriptions of the identical components will be omitted.

Referring to FIG. 9, a first planarization layer pattern 117ia and a second planarization layer pattern 117ib which surround the light emitting element LED are disposed on the first connection electrode CE1. The first planarization layer pattern 117ia and the second planarization layer pattern 117ib are disposed to cover a portion of the first connection electrode CE1 which covers the light emitting element LED and an upper portion of the light emitting element LED. The second electrode 125 of the light emitting element LED is exposed from the first planarization layer pattern 117ia and the second planarization layer pattern 117ib to be connected to the second connection electrode CE2.

The first planarization layer pattern 117ia can be formed of the same material on the same layer as the second planarization layer 117b, and the second planarization layer pattern 117ib can be formed of the same material on the same layer as the third planarization layer 117c, but is not limited thereto. In example embodiments of the present disclosure, the first planarization layer pattern 117ia and the second planarization layer 117b can be both formed of different materials from those of the second planarization layer 117b and the third planarization layer 117c, or can both be formed of only one of the material from the second planarization layer 117b and the third planarization layer 117c, and the second planarization layer pattern 117ib, but is not limited thereto. In example embodiments of the present disclosure, heights of the first planarization layer pattern 117ia, the second planarization layer 117b, or the planarization layer pattern 117i can be aligned with a height of the second planarization layer 117b, but is not limited thereto. For example, upper surfaces of the first planarization layer pattern 117ia, the second planarization layer 117b, or the planarization layer pattern 117i can be a same height, or can be higher or lower than the upper surface of the second planarization layer 117b, but is not limited thereto.

The first connection electrode CE1 and the second connection electrode CE2 can be disposed on different layers by the first planarization layer pattern 117ia and the second planarization layer pattern 117ib, and a short circuit defect of the first connection electrode CE1 and the second connection electrode CE2 can be suppressed.

Accordingly, in the display device 900 according to still another example embodiment of the present disclosure, the upper portion of the light emitting element LED can cover the upper portion of the light emitting element LED with the plurality of planarization layer patterns 117ia and 117ib. The plurality of planarization layer patterns 117ia and 117ib can be used to easily cover the upper portion of the light emitting element LED. In particular, the plurality of planarization layer patterns 117ia and 117ib can cover all the first connection electrodes CE1 in the opening of the fourth planarization layer 117d, thereby preventing a short-circuit defect of the first connection electrode CE1 and the second connection electrode CE2. Accordingly, a plurality of planarization layer patterns 117ia and 117ib can be used in consideration of the step difference of the light emitting element LED.

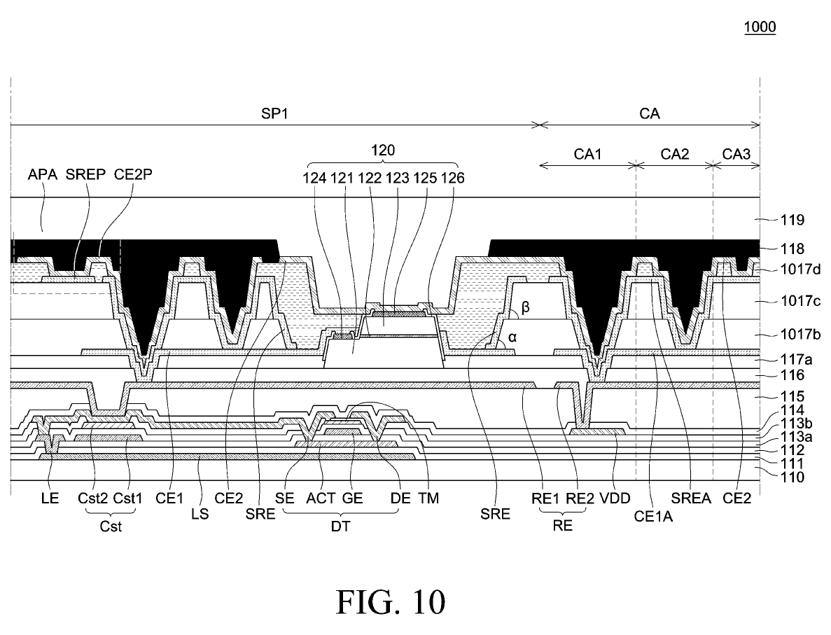

FIG. 10 is a cross-sectional view of a display device according to still another example embodiment of the present disclosure. The only difference between a display device 1000 of FIG. 10 and the display device 700 of FIGS. 7 and 8 is a second planarization layer 1017b, a third planarization layer 1017c, and a fourth planarization layer 1017d, but the other configuration is substantially the same, so that a redundant description will be omitted.

Referring to FIG. 10, a side surface of the second planarization layer 1017b can have a first angle α, a side surface of the third planarization layer 1017c can have a second angle β, and the first angle α and the second angle β can be different from each other. For example, the second angle β can be an angle of 60 degrees or less, and the first angle α can be an angle smaller than the second angle β. For example, the second angle β can be about 55 degrees, and the first angle α can be smaller than the second angle β, but is not limited thereto.

The first angle α of the side surface of the second planarization layer 1017b and the second angle β of the side surface of the third planarization layer 1017c can be configured to be different from each other. In this case, both the first angle α and the second angle β can be an angle of 60 degrees or less, and at least one of the first angle α and the second angle β can have an angle of about 55 degrees. At least one of the first angle α and the second angle β can be designed as an angle to compensate for the luminance non-uniformity according to the viewing angle, thereby improving the luminance uniformity of the display device 1000.

Next, the fourth planarization layer 1017d is disposed to cover the light emitting element LED and the first connection electrode CE1. The fourth planarization layer 1017d is disposed to cover an upper portion of the light emitting element LED and can separate the first connection electrode CE1 and the second connection electrode CE2. In the fourth planarization layer 1017d, only the second electrode 125 of the light emitting element LED is exposed so that the second electrode 125 and the second connection electrode CE2 can be connected to each other. Accordingly, the fourth planarization layer 1017d can serve as an insulating layer which separates the first connection electrode CE1 and the second connection electrode CE2 and as a planarization layer pattern 117i which guides the second electrode 125 and the second connection electrode CE2 to be self-aligned.

Accordingly, in the display device 1000 according to still another example embodiment of the present disclosure, the fourth planarization layer 1017d can be used as the planarization layer pattern 117i for self-alignment of the light emitting element LED and the second connection electrode CE2, thereby simplifying the structure of the display device 1000.

### The example embodiments of the present disclosure can also be described as follows

According to an embodiment of the present disclosure, a display device includes a substrate on which a plurality of sub pixels and a plurality of contact areas between the plurality of sub pixels are defined, light emitting elements disposed in each of the plurality of sub pixels, a side reflection plate disposed in each of the plurality of sub pixels and surrounding the light emitting elements, a first connection electrode electrically connected to a first electrode of the light emitting element, a planarization layer pattern covering the first connection electrode and the light emitting element, and a second connection electrode disposed on the planarization layer pattern, in which the first connection electrode and the second connection electrode are spaced apart from each other with the planarization layer pattern therebetween.

According to another aspect of the present disclosure, the light emitting element can further include a first semiconductor layer in which the first electrode is disposed on the top surface, a emission layer on the first semiconductor layer, a second semiconductor layer on the emission layer, and a second electrode on the top surface of the second semiconductor layer, and the second electrode can be exposed from the planarization layer pattern and connected to the second connection electrode.

According to yet another aspect of the present disclosure, the display device can further include a first planarization layer disposed below the first connection electrode and surrounding a lower portion of the light emitting element, a second planarization layer disposed on the first connection electrode, a third planarization layer disposed between the second planarization layer and the side reflection plate, and a fourth planarization layer disposed between the side reflection plate and the second connection electrode, the second planarization layer and the third planarization layer can include an opening overlapping the light emitting element, wherein a side surface of the second planarization layer and a side surface of the third planarization layer in the opening can be disposed to be spaced apart from the light emitting element.

According to yet another aspect of the present disclosure, the planarization layer pattern can be formed of the same material as either the second planarization layer or the third planarization layer.

According to yet another aspect of the present disclosure, the planarization layer pattern can include a first planarization layer pattern made of the same material as the second planarization layer, and a second planarization layer pattern made of the same material as the third planarization layer.

According to yet another aspect of the present disclosure, the planarization layer pattern can be exposed from the fourth planarization layer.

According to yet another aspect of the present disclosure, the planarization layer pattern can be integrally formed with the fourth planarization layer.

According to yet another aspect of the present disclosure, the side surface of the third planarization layer can be disposed on the second planarization layer and spaced apart from the side surface of the second planarization layer, such that the side surface of the second planarization layer and the side surface of the third planarization layer can form a stepped structure.

According to yet another aspect of the present disclosure, a side surface of the second planarization layer can have a first angle, a side surface of the third planarization layer can have a second angle, and the first angle and the second angle can be 60 degrees or less.

According to yet another aspect of the present disclosure, the first angle and the second angle can be different.

According to yet another aspect of the present disclosure, the side reflection plate can be disposed on a side surface of the second planarization layer and a side surface of the third planarization layer in the opening, and an interval between the side reflection plate and the light emitting element can be constant in one sub pixel among the plurality of sub pixels.

According to yet another aspect of the present disclosure, the side reflection plate can be electrically connected to the first connection electrode through a plurality of contact holes.

According to yet another aspect of the present disclosure, the display device can further include a driving transistor disposed in each of the plurality of sub pixels, a first reflective electrode disposed on the driving transistor and electrically connected to the driving transistor, a power line disposed in the plurality of contact areas, a second reflective electrode disposed on the power line in the plurality of contact areas and electrically connected to the power line, a first contact electrode disposed on the same layer as the first connection electrode and electrically connected to the second reflective electrode, and a second contact electrode disposed on the same layer as the side reflection plate and electrically connected to the first contact electrode, the second connection electrode can extend from the plurality of sub pixels to the plurality of contact areas and electrically connected to the second contact electrode.

According to yet another aspect of the present disclosure, the plurality of contact areas can include a first contact area in which the second reflective electrode, the first contact electrode, the second contact electrode, and the second connection electrode are electrically connected to each other, a second contact area in which the first contact electrode, the second contact electrode, and the second connection electrode are electrically connected to each other, and a third contact area in which the second contact electrode and the second connection electrode are electrically connected to each other.

According to yet another aspect of the present disclosure, the display device can further include an inspection area disposed in each of the plurality of sub pixels, a first inspection pad disposed on the third planarization layer in the inspection area, and a second inspection pad disposed on the fourth planarization layer in the inspection area. The first inspection pad and the second inspection pad can be electrically connected to the first connection electrode.

According to yet another aspect of the present disclosure, the first inspection pad can be electrically connected to the first connection electrode through a side reflection plate, and the second inspection pad can be electrically connected to the first inspection pad through a contact hole of the fourth planarization layer.

According to yet another aspect of the present disclosure, the second planarization layer can include a first lower edge having a concave arc shape and a first upper edge having a convex arc shape in the opening, and the third planarization layer can include a second lower edge having a concave arc shape and a second upper edge having a convex arc shape in the opening.

According to yet another aspect of the present disclosure, the first upper edge and the second upper edge can have an arc shape having the same radius.

According to yet another aspect of the present disclosure, the curvature of the first lower edge can be greater than the curvature of the second upper edge.

According to yet another aspect of the present disclosure, the arc of the second lower edge can be disposed at the end of the arc of the first upper edge.

Although the example embodiments of the present disclosure have been described in detail with reference to the accompanying drawings, the present disclosure is not limited thereto and can be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all embodiments and do not limit the present disclosure. All the technical concepts in the equivalent scope of the present disclosure should be construed as falling within the scope of the present disclosure.

What is claimed is:

1. A display device, comprising:
a substrate on which a plurality of sub pixels are disposed;
a light emitting element disposed in the plurality of sub pixels;
a side reflection plate disposed in one of the plurality of sub pixels and adjacent to the light emitting element;
a first connection electrode electrically connected to a first electrode of the light emitting element;
a planarization layer pattern disposed on the first connection electrode and the light emitting element; and
a second connection electrode disposed on the planarization layer pattern,
wherein the first connection electrode and the second connection electrode are spaced apart from each other with the planarization layer pattern interposed therebetween.

2. The display device according to claim 1, wherein the light emitting element further includes:
a first semiconductor layer having a top surface on which the first electrode is disposed;
an emission layer on the first semiconductor layer;
a second semiconductor layer on the emission layer; and
a second electrode on a top surface of the second semiconductor layer, and
wherein the second electrode is exposed from the planarization layer pattern and connected to the second connection electrode.

3. The display device according to claim 2, further comprising:
a first planarization layer disposed below the first connection electrode and adjacent to a lower portion of the light emitting element;
a second planarization layer disposed on the first connection electrode;
a third planarization layer disposed between the second planarization layer and the side reflection plate; and
a fourth planarization layer disposed between the side reflection plate and the second connection electrode,
wherein the second planarization layer and the third planarization layer define an opening overlapping the light emitting element, and
wherein a side surface of the second planarization layer and a side surface of the third planarization layer in the opening are disposed to be spaced apart from the light emitting element.

4. The display device according to claim 3, wherein the planarization layer pattern includes a same material as either the second planarization layer or the third planarization layer.

5. The display device according to claim 3, wherein the planarization layer pattern includes:
a first planarization layer pattern includes a same material as the second planarization layer; and
a second planarization layer pattern disposed on the first planarization layer pattern and includes a same material as the third planarization layer.

6. The display device according to claim 3, wherein the planarization layer pattern is exposed from the fourth planarization layer.

7. The display device according to claim 3, wherein the planarization layer pattern is integrally formed with the fourth planarization layer.

8. The display device according to claim 3, wherein a side surface of the third planarization layer is disposed on the second planarization layer to be spaced apart from a side surface of the second planarization layer, and a side surface of the second planarization layer and a side surface of the third planarization layer form a stepped structure.

9. The display device according to claim 8, wherein a side surface of the second planarization layer has a first angle, a side surface of the third planarization layer has a second angle, and
wherein the first angle and the second angle are 60 degrees or less.

10. The display device according to claim 9, wherein the first angle and the second angle are different from each other.

11. The display device according to claim 9, wherein the first angle and the second angle are about 55 degrees, and light emitted from the light emitting element is directed towards a center of an emission area of the light emitting element so that a luminance distribution across a viewing angle of the display device is approximately uniform.

12. The display device according to claim 8, wherein in the opening, the side reflection plate is disposed on a side surface of the second planarization layer and a side surface of the third planarization layer, and
wherein an interval between the side reflection plate and the light emitting element is constant in one of the plurality of sub pixels.

13. The display device according to claim 8, wherein the side reflection plate is electrically connected to the first connection electrode through a plurality of contact holes.

14. The display device according to claim 8, wherein a plurality of contact areas are further defined between the plurality of sub pixels on the substrate,
wherein the display device further comprises:
a driving transistor disposed in each of the plurality of sub pixels;
a first reflective electrode disposed on the driving transistor and electrically connected to the driving transistor;
a power line disposed in the plurality of contact areas;
a second reflective electrode disposed on the power line in the plurality of contact areas and electrically connected to the power line;
a first contact electrode disposed on a same layer as the first connection electrode and electrically connected to the second reflective electrode; and
a second contact electrode disposed on the same layer as the side reflection plate and electrically connected to the first contact electrode, and
wherein the second connection electrode extends from the plurality of sub pixels to the plurality of contact areas and is electrically connected to the second contact electrode.

15. The display device according to claim 14, wherein the plurality of contact areas includes:
a first contact area in which the second reflective electrode, the first contact electrode, the second contact electrode, and the second connection electrode are electrically connected to each other;
a second contact area in which the first contact electrode, the second contact electrode, and the second connection electrode are electrically connected to each other; and
a third contact area in which the second contact electrode and the second connection electrode are electrically connected to each other.

16. The display device according to claim 15, wherein the second connection electrode is in contact with the first contact electrode and the second contact electrode at respective contact points within the first contact area, the second contact area, and third contact area.

17. The display device according to claim 3, further comprising:
an inspection area disposed in each of the plurality of sub pixels;
a first inspection pad disposed on the third planarization layer in the inspection area; and
a second inspection pad disposed on the fourth planarization layer in the inspection area,
wherein the first inspection pad and the second inspection pad are electrically connected to the first connection electrode.

18. The display device according to claim 17, wherein the first inspection pad is electrically connected to the first connection electrode through the side reflection plate, and
wherein the second inspection pad is electrically connected to the first inspection pad through a contact hole of the fourth planarization layer.

19. The display device according to claim 8, wherein the second planarization layer includes a first lower edge having a concave arc shape and a first upper edge having a convex arc shape in the opening, and
wherein the third planarization layer includes a second lower edge having a concave arc shape and a second upper edge having a convex arc shape in the opening.

20. The display device according to claim 19, wherein the first upper edge and the second upper edge have an arc shape having a same radius.

21. The display device according to claim 19, wherein a curvature of the first lower edge is greater than a curvature of the second upper edge.

22. The display device according to claim 19, wherein arcs of the second lower edge are continuously disposed at the ends of the arcs of the first upper edge.

23. The display device according to claim 19, wherein at least a portion of the side reflection plate is formed as a curved surface following respective arc shapes of the first lower edge and the first upper edge to increase light reflection efficiency of the side reflection plate.

24. The display device according to claim 1, wherein the side reflection plate is electrically connected to the first connection electrode to avoid a floating state, and prevent generation of static electricity therein.

25. The display device according to claim 1, wherein the plurality of sub pixels includes a first sub pixel having a circular shaped opening, and a second sub pixel having an oval shaped opening, and
wherein intervals between the light emitting element and the side reflection plate are constant in the first sub pixel and the second sub pixel, respectively.

26. A display device, comprising:
a substrate including a display area and an inspection area;
a planarization structure disposed on the substrate, the planarization structure comprising a first planarization layer, a second planarization layer, and a third planarization layer and a fourth planarization layer, the second planarization layer and third planarization layer defining an opening having an inclined side surface;
a light emitting element disposed within the opening;
a first connection electrode and a second connection electrode electrically connected to the light emitting element;
a side reflection plate disposed on side surfaces of both the second planarization layer and the third planarization layer; and
an insulating planarization pattern disposed within the opening and covering the first connection electrode and a side surface of the light emitting element,
wherein a top surface of the light emitting element is exposed from the insulating planarization pattern and is electrically connected to the second connection electrode.

27. The display device according to claim 26, wherein the side surface of the third planarization layer is laterally offset from the side surface of the second planarization layer by a distance to form a stepped structure on a top surface of the second planarization layer within the opening.

28. The display device according to claim 26, wherein the light emitting element comprises a first electrode and a second electrode, and
wherein the first electrode and the second electrode are separated by about a thickness of the insulating planarization pattern.

29. The display device according to claim 26, further comprising an inspection pad positioned in the inspection area within the sub-pixel, the inspection pad comprising:
a first inspection pad disposed on the third planarization layer and includes a same material as the side reflection plate; and
a second inspection pad disposed on the fourth planarization layer and includes a same material as the second connection electrode,
wherein the first inspection pad and the second conductive pads are vertically aligned in the inspection area and electrically coupled to the light emitting element.

30. The display device according to claim 26, wherein the second planarization layer includes a first lower edge having a first radius of curvature and the third planarization layer includes a second lower edge having a second radius of curvature, and
wherein the first radius of curvature is smaller than the second radius of curvature.
